(19) United States
(12) Patent Application Publication
(10) Pub. No.: US 2013/0118577 A1
(43) Pub. Date: May 16, 2013

(54) Thin Film Type Solar Cell and Method for Manufacturing the Same

(71) Applicants: Jae Ho KIM, Yongin-si (KR); JIN HONG, Yongin-si (KR)

(72) Inventors: Jae Ho KIM, Yongin-si (KR); JIN HONG, Yongin-si (KR)

(21) Appl. No.: 13/733,768

(22) Filed: Jan. 3, 2013

Related U.S. Application Data
(62) Division of application No. 12/456,115, filed on Jun. 11, 2009.

(30) Foreign Application Priority Data
Jun. 12, 2008 (KR) 10-2008-0055024

(51) Int. Cl. H01L 31/0224

(52) U.S. Cl. CPC H01L 31/022425
USPC 136/256

(57) ABSTRACT

A thin film type solar cell and a method for manufacturing the same is disclosed, wherein the thin film type solar cell includes a first anti-oxidation layer formed on a front electrode, and a semiconductor layer formed on the first anti-oxidation layer, so that it is possible to prevent an oxide from being formed in the interface between the front electrode and the semiconductor layer by preventing a reaction between an oxidant contained in the front electrode and silicon of the semiconductor layer, to thereby realize improved cell efficiency, wherein the method for manufacturing the thin film type solar cell comprises forming the front electrode on a substrate; forming the first anti-oxidation layer on the front electrode; forming the semiconductor layer on the first anti-oxidation layer; and forming a rear electrode on the semiconductor layer.

### CROSS REFERENCE TO RELATED APPLICATIONS

This application claims the benefit of U.S. patent application Ser. No. 12/465,115, filed on Jun. 11, 2009, pending, which in turn claims the benefit of Korean Patent Application No. P2008-0055024, filed on Jun. 12, 2008, both of which are hereby incorporated by reference as if fully set forth herein.

### BACKGROUND OF THE INVENTION

1. Field of the Invention

The present invention relates to a solar cell, and more particularly, to a thin film type solar cell.

2. Discussion of the Related Art

A solar cell with a property of semiconductor converts light energy into electric energy.

A structure and principle of the solar cell according to the related art will be briefly explained as follows. The solar cell is formed in a PN junction structure where a positive (P)-type semiconductor makes a junction with a negative (N)-type semiconductor. When a solar ray is incident on the solar cell with the PN junction structure, holes (+) and electrons (−) are generated in the semiconductor owing to the energy of the solar ray. By an electric field generated in a PN junction area, the holes (+) are drifted toward the P-type semiconductor and the electrons (31 ) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. However, in the case of the wafer type solar cell, it is difficult to realize a small thickness due to difficulty in performance of the manufacturing process. In addition, the wafer type solar cell uses a high-priced semiconductor substrate, whereby its manufacturing cost is increased.

Even though the thin film type solar cell is inferior in efficiency to the wafer type solar cell, the thin film type solar cell has advantages such as realization of a thin profile and use of low-priced material. Accordingly, the thin film type solar cell is suitable for a mass production.

The thin film type solar cell is manufactured by sequential steps of forming a front electrode on a glass substrate, forming a semiconductor layer on the front electrode, and forming a rear electrode on the semiconductor layer. Hereinafter, a related art thin film type solar cell will be explained with reference to the accompanying drawings.

FIGS. 1A-1D is a series of cross section views illustrating a related art method for manufacturing the related art thin film type solar cell.

As shown in FIG. 1A, a front electrode 20 is formed on a glass substrate 10. The front electrode 20 is formed of a metal oxide.

Next, as shown in FIG. 1B, a semiconductor layer 40 is formed on the front electrode 20. The semiconductor layer 40 is formed of a silicon compound.

As shown in an enlarged view of FIG. 1B, an oxide 43 may be formed in an interface between the front electrode 20 and the semiconductor layer 40. In more detail, since the front electrode 20 is formed of the metal oxide, the front electrode 20 contains oxygen therein.

Also, if the front electrode 20 is exposed to the atmosphere before carrying out a process of forming the semiconductor layer 40, an OH group may be adsorbed onto the surface of the front electrode 20. When the semiconductor layer 40 is formed on the front electrode 20 containing an oxidant such as oxygen or OH group, the oxidant contained in the front electrode 20 reacts with the silicon of the semiconductor layer 40, thereby forming a silicon oxide. If an oxide 43 such as the silicon oxide is formed in the interface between the front electrode 20 and the semiconductor layer 40, a contact resistance may be increased therein due to the oxide 43. Accordingly, the increased contact resistance may cause a problematic deterioration in cell efficiency.

As shown in FIG. 1C, a transparent conductive layer 60 is formed on the semiconductor layer 40. The transparent conductive layer 60 is formed of a metal oxide.

In this case, as known from an enlarged view of FIG. 1C, an oxide 46 may be formed in the interface between the semiconductor layer 40 and the transparent conductive layer 60. In more detail, since the transparent conductive layer 60 is formed of the metal oxide, oxygen reacts with the silicon of the semiconductor layer 40 during a process of forming the transparent conductive layer 60, thereby forming a silicon oxide. Also, if the semiconductor layer 40 is exposed to the atmosphere before carrying out a process of forming the transparent conductive layer 60, an OH group may be adsorbed onto the surface of the semiconductor layer 40. Under this circumstance, if forming the transparent conductive layer 60, the OH group reacts with the silicon of the semiconductor layer 40, thereby forming a silicon oxide. Then, if an oxide 46 such as the silicon oxide is formed in the interface between the semiconductor layer 40 and the transparent conductive layer 60, a contact resistance may be increased therein due to the oxide 46. Accordingly, the increased contact resistance may cause a problematic deterioration in cell efficiency.

As shown in FIG. 1D, a rear electrode 70 is formed on the transparent conductive layer 60, thereby completing the process of manufacturing the thin film type solar cell.

As mentioned above, the related art thin film type solar cell includes the oxides 43 and 46, wherein the oxide 43 is formed in the interface between the front electrode 20 and the semiconductor layer 40, and the oxide 46 is formed in the interface between the semiconductor layer 40 and the transparent conductive layer 60. The oxides 43 and 46 cause the increase of contact resistance, and further, the increased contact resistance causes the deterioration of cell efficiency.

### SUMMARY OF THE INVENTION

Accordingly, the present invention is directed to a thin film type solar cell and a method for manufacturing the same that substantially obviates one or more problems due to limitations and disadvantages of the related art.

An object of the present invention is to provide a thin film type solar cell and a method for manufacturing the same, which is capable of improving cell efficiency by preventing an oxide from being formed in an interface between a front electrode and a semiconductor layer, or between the semiconductor layer and a transparent conductive layer.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for manufacturing a thin film type solar cell comprises forming a front electrode on a substrate; forming a first anti-oxidation layer on the front electrode; forming a semiconductor layer on the first anti-oxidation layer; and forming a rear electrode on the semiconductor layer.

In another aspect of the present invention, a method for manufacturing a thin film type solar cell comprises forming a front electrode on a substrate; removing an oxidant from the front electrode; forming a semiconductor layer on the front electrode from which the oxidant is removed; and forming a rear electrode on the semiconductor layer.

In another aspect of the present invention, a method for manufacturing a thin film type solar cell comprises forming a front electrode on a substrate; forming a semiconductor layer on the front electrode; removing an oxidant from the semiconductor layer; forming a transparent conductive layer on the semiconductor layer from which the oxidant is removed; and forming a rear electrode on the transparent conductive layer.

In another aspect of the present invention, a method for manufacturing a thin film type solar cell comprises forming a front electrode on a substrate; forming a semiconductor layer on the front electrode; forming a second anti-oxidation layer on the semiconductor layer; forming a transparent conductive layer on the second anti-oxidation layer; and forming a rear electrode on the transparent conductive layer, wherein the second anti-oxidation layer is formed of a material which doesn't contain oxygen therein.

In another aspect of the present invention, a thin film type solar cell comprises a front electrode on a substrate; a first anti-oxidation layer on the front electrode; a semiconductor layer on the first anti-oxidation layer; and a rear electrode on the semiconductor layer.

In another aspect of the present invention, a thin film type solar cell comprises a front electrode on a substrate; a semiconductor layer on the front electrode; a second anti-oxidation layer on the semiconductor layer; a transparent conductive layer on the second anti-oxidation layer; and a rear electrode on the transparent conductive layer, wherein the second anti-oxidation layer is formed of a material which doesn't contain oxygen therein.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A-1D are a series of cross section views illustrating a method for manufacturing a related art thin film type solar cell;

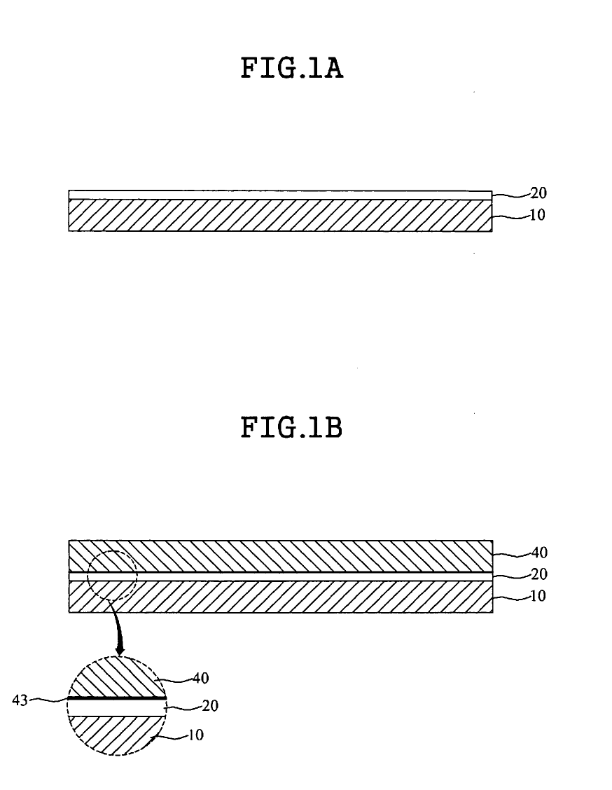

FIGS. 2A-2H are a series of cross section views illustrating a method for manufacturing a thin film type solar cell according to one embodiment of the present invention;

FIG. 3 is a cross section view illustrating a thin film type solar cell according to one embodiment of the present invention;

FIG. 4 is a cross section view illustrating a thin film type solar cell according to another embodiment of the present invention; and

FIG. 5 is a cross section view illustrating a thin film type solar cell according to another embodiment of the present invention.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

Hereinafter, a thin film type solar cell according to the present invention and a method for manufacturing the same will be described with reference to the accompanying drawings.

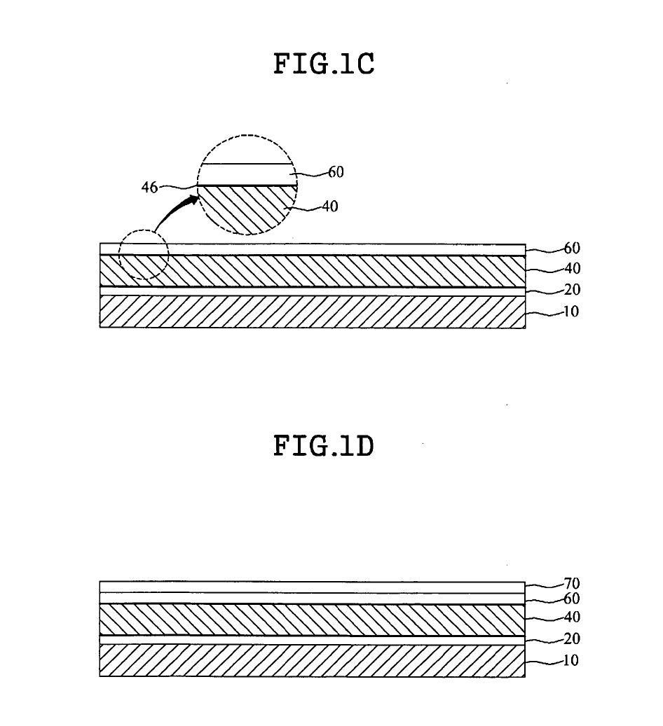

FIGS. 2A-2H are a series of cross section views illustrating a method for manufacturing a thin film type solar cell according to one embodiment of the present invention.

First, as shown in FIG. 2A, a front electrode 200 is formed on a substrate 100.

The front electrode 200 is formed of a transparent conductive material, for example, ZnO, ZnO:B, ZnO:Al, ZnO:H, SnO₂, SnO₂:F, or ITO (Indium Tin Oxide) by sputtering or MOCVD (Metal Organic Chemical Vapor Deposition).

In order to maximize solar-ray absorbing efficiency, the front electrode 200 may have an uneven surface which is formed by a texturing process. The texturing process may, for example, be an etching process using photolithography, an anisotropic etching process using a chemical solution, or a groove-forming process using a mechanical scribing. If applying the texturing process to the front electrode 200, a solar-ray reflection ratio on the solar cell is decreased, and a solar-ray absorbing ratio into the solar cell is increased owing to a dispersion of the solar ray, thereby improving cell efficiency.

As shown in FIG. 2B, a hydrogen (H₂) plasma treatment is applied to the front electrode 200.

If the front electrode 200 is exposed to the atmosphere during the manufacturing process, an OH group may be adsorbed onto the surface of the front electrode 200. Also, since the front electrode 200 is formed of a metal oxide, the front electrode 200 contains oxygen therein. Accordingly, an oxidant such as oxygen or OH group, contained in the front electrode 200, can be removed by deoxidization through the hydrogen (H₂) plasma treatment.

Then, as shown in FIG. 2C, a first anti-oxidation layer 300 is formed on the front electrode 200.

As explained above, even though the oxidant is removed to some degree from the front electrode 200 by the hydrogen (H₂) plasma treatment, the oxidant may remain still in the front electrode 200. Due to the remaining oxidant, an impurity such as a silicon oxide may be formed in the front electrode 200. In this reason, the first anti-oxidation layer 300 is additionally formed on the front electrode 200 so as to prevent the silicon oxide from being formed on the front electrode 200.

When forming the first anti-oxidation layer 300 so as to prevent the formation of silicon oxide, the following conditions must be satisfied.

First, an oxide should not be formed in the interface between the front electrode 200 and the first anti-oxidation layer 300. For this, the first anti-oxidation layer 300 is formed of a material having a low oxidation degree.

Second, an oxide should not be formed in the interface between the first anti-oxidation layer 300 and a semiconductor layer to be described (see semiconductor layer 400 in FIG. 2D). In order to satisfy this condition, the first anti-oxidation layer 300 should not contain the oxidant therein. That is, the first anti-oxidation layer 300 should be formed of a material which doesn't contain oxygen therein. Preferably, the first anti-oxidation layer 300 is not exposed to the atmosphere. In order to prevent the first anti-oxidation layer 300 from being exposed to the atmosphere, it is preferable that a process of forming the semiconductor layer 400 follow a process of forming the first anti-oxidation layer 300 in sequence.

Third, the first anti-oxidation layer 300 should be formed of a material having a high electric conductivity. This is because a material with a low electric conductivity can cause deterioration of cell efficiency.

Fourth, it is necessary to prevent a solar-ray transmittance from being lowered by the first anti-oxidation layer 300. If the solar-ray transmittance is lowered due to the first anti-oxidation layer 300, the solar-ray absorbing efficiency is lowered so that the cell efficiency is also lowered.

A material of the first anti-oxidation layer 300, which is suitable for satisfying the aforementioned first to fourth conditions, may be germanium (Ge). The germanium (Ge) can be formed under the atmosphere of hydrogen (H₂) plasma by ALD (Atomic Layer Deposition) using GeH₄ gas. Also, the fourth condition to prevent lowering of the solar-ray transmittance can be accomplished by adjusting the thickness of the first anti-oxidation layer 300. Preferably, the first anti-oxidation layer 300 is formed at a thickness between 10 Å (1×10⁻¹¹ m) and 30 Å (3×10⁻¹¹ m). If the thickness of the first anti-oxidation layer 300 is less than 10 Å, it may cause the deterioration of oxidation-preventing efficiency. Meanwhile, if the thickness of the first anti-oxidation layer 300 is more than 30 Å, it may cause the deterioration of solar-ray transmittance.

As shown in FIG. 2(D), the semiconductor layer 400 is formed on the first anti-oxidation layer 300. As mentioned above, it is preferable that the process of forming the semiconductor layer 400 sequentially follow the process of forming the first anti-oxidation layer 300 so as to prevent the first anti-oxidation layer 300 from being exposed to the atmosphere.

The semiconductor layer 400 is formed of a silicon-based semiconductor material by plasma chemical vapor deposition (CVD), wherein the semiconductor layer 400 may be formed in a PIN structure where a P-type semiconductor layer, an I-type semiconductor layer, and an N-type semiconductor layer are deposited in sequence. In the semiconductor layer 400 with the PIN structure, depletion is generated in the I-type semiconductor layer by the P-type semiconductor layer and the N-type semiconductor layer, whereby an electric field occurs in the I-type semiconductor layer. Thereafter, holes and electrons generated by the solar ray are drifted by the electric field, and then are respectively collected in the P-type semiconductor layer and the N-type semiconductor layer.

If forming the semiconductor layer 400 with the PIN structure, preferably the P-type semiconductor layer is firstly formed on the first anti-oxidation layer 300, and then the I-type and N-type semiconductor layers are formed thereon. This is because a drift mobility of the hole is less than a drift mobility of the electron. In order to maximize the efficiency in collection of the incident light, the P-type semiconductor layer is provided adjacent to the light-incidence face.

As shown in FIG. 2E, a hydrogen (H₂) plasma treatment is applied to the semiconductor layer 400.

If the semiconductor layer 400 is exposed to the atmosphere during the manufacturing process, an OH group may be adsorbed onto the surface of the semiconductor layer 400. Accordingly, an oxidant such as the OH group which exists in the surface of the semiconductor layer 400 can be removed by deoxidization through the hydrogen (H₂) plasma treatment.

However, if the process of forming the semiconductor layer 400 and the following process are sequentially carried out, that is, if the semiconductor layer 400 is not exposed to the atmosphere, the OH group doesn't exist in the surface of the semiconductor layer 400 by adsorption. Thus, there is no requirement for the hydrogen (H₂) plasma treatment.

Next, as shown in FIG. 2F, a second anti-oxidation layer 500 is formed on the semiconductor layer 400.

The second anti-oxidation layer 500 may be formed of the same material as that of the first anti-oxidation layer 300. That is, the second anti-oxidation layer 500 may be formed of a germanium (Ge) layer which can be made under the atmosphere of hydrogen (H₂) plasma by ALD (Atomic Layer Deposition) using GeH₄ gas. Also, the second anti-oxidation layer 500 can be formed at a thickness between 10 Å (1×10⁻¹¹ m) and 30 Å (3×10⁻¹¹ m).

Then, as shown in FIG. 2G, a transparent conductive layer 600 is formed on the second anti-oxidation layer 500. In order to prevent the second anti-oxidation layer 500 from being exposed to the atmosphere, the process of forming the transparent conductive layer 600 sequentially follows the process of forming the second anti-oxidation layer 500, preferably.

The transparent conductive layer 600 may be formed of a transparent conductive layer such as ZnO by sputtering or MOCVD (Metal Organic Chemical Vapor Deposition).

The transparent conductive layer 600 may be omitted. Preferably, the transparent conductive layer 600 is provided so as to improve the cell efficiency. This is because the transparent conductive layer 600 enables the solar ray transmitted through the semiconductor layer 400 to be dispersed in all angles, whereby the solar ray is reflected on a rear electrode to be described (see rear electrode 700 in FIG. 2H) and is then re-incident on the semiconductor layer 400, thereby resulting in the improved cell efficiency.

As shown in FIG. 2H, the rear electrode 700 is formed on the transparent conductive layer 600, thereby completing the process of manufacturing the thin film type solar cell according to one embodiment of the present invention.

The rear electrode 700 may be formed of metal, for example, Ag, Al, Ag+Al, Ag+Mg, Ag+Mn, Ag+Sb, Ag+Zn, Ag+Mo, Ag+Ni, Ag+Cu, or Ag+Al+Zn by a screen printing method, an inkjet printing method, a gravure printing method, or a micro-contact printing method.

Herein, the method for manufacturing the thin film type solar cell according to one embodiment of the present invention has been explained. Although not explained herein, all methods suitable for preventing the oxide from being formed in the interface between the front electrode 200 and the semiconductor layer 400 or between the semiconductor layer 400 and the transparent conductive layer 600 can be included in the present invention. That is, the present invention includes all methods which can prevent the oxide from being formed in the specific interface by comparison to the related art, even though each method is made with an omission of any process among FIGS. 2A-2H. The detailed examples will be explained as follows.

First, any one of the hydrogen (H₂) plasma treatment applied to the front electrode 200 (the process of FIG. 2B) and the process of forming the first anti-oxidation layer 300 on the front electrode 200 (the process of FIG. 2C) may be selectively carried out. That is, after forming the front electrode 200 on the substrate 100 as shown in FIG. 2A, the process of FIG. 2B may be omitted, and the first anti-oxidation layer 300 may be directly formed on the front electrode 200. In another aspect, after forming the front electrode 200 on the substrate 100 as shown in FIG. 2A, the hydrogen (H₂) plasma treatment may be applied to the front electrode 200 as shown in FIG. 2B, and the process of FIG. 2C may be omitted.

Second, any one of the hydrogen (H₂) plasma treatment applied to the semiconductor layer 400 (the process of FIG. 2E) and the process of forming the second anti-oxidation layer 500 (the process of FIG. 2F) may be selectively carried out. That is, after forming the semiconductor layer 400 as shown in FIG. 2D, the process of FIG. 2E may be omitted, and the second anti-oxidation layer 500 may be directly formed on the semiconductor layer 400 as shown in FIG. 2F. In another aspect, after forming the semiconductor layer 400 as shown in FIG. 2D, the hydrogen (H₂) plasma treatment may be applied to the semiconductor layer 400 as shown in FIG. 2E, and the process of FIG. 2F may be omitted.

Third, any one of the process of forming the first anti-oxidation layer 300 (the process of FIG. 2C) and the process of forming the second anti-oxidation layer 500 (the process of FIG. 2E) may be selectively carried out. That is, the first anti-oxidation layer 300 may be formed between the front electrode 200 and the semiconductor layer 400 without forming the second anti-oxidation layer 500 between the semiconductor layer 400 and the transparent conductive layer 600. In another aspect, the second anti-oxidation layer 500 may be formed between the semiconductor layer 400 and the transparent conductive layer 600 without forming the first anti-oxidation layer 300 between the front electrode 200 and the semiconductor layer 400.

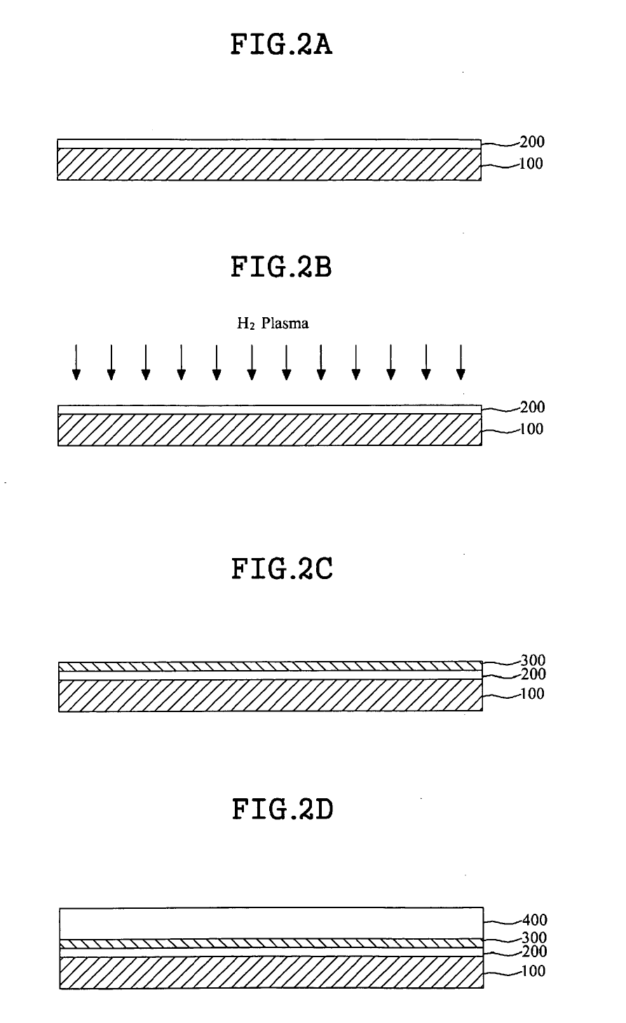

FIG. 3 is a cross section view illustrating a thin film type solar cell according to one embodiment of the present invention.

As shown in FIG. 3, the thin film type solar cell according to one embodiment of the present invention includes a substrate 100, a front electrode 200, a first anti-oxidation layer 300, a semiconductor layer 400, a transparent conductive layer 600, and a rear electrode 700.

The substrate 100 is formed of glass or transparent plastic.

The front electrode 200 is formed on the substrate 100. The front electrode 200 is formed of a transparent conductive material, for example, ZnO, ZnO:B, ZnO:Al, ZnO:H, SnO₂, SnO₂:F, or ITO (Indium Tin Oxide). Also, the front electrode 200 may have an uneven surface.

The first anti-oxidation layer 300 prevents an oxide from being formed in the interface between the front electrode 200 and the semiconductor layer 400. The first anti-oxidation layer 300 is formed of a material which has a low oxidation degree, contains no oxygen therein, and obtains a high electric conductivity and a high solar-ray transmittance. For example, the first anti-oxidation layer 300 may be formed of a germanium (Ge) layer. Also, the first anti-oxidation layer 300 may be formed at a thickness between 10 Å (1×10⁻¹¹ m) and 30 Å (3×10⁻¹¹ m). This is because the first anti-oxidation layer 300 having the thickness less than 10 Å may cause deterioration of oxidation preventing efficiency and the first anti-oxidation layer 300 having the thickness more than 30 Å may cause lowering of solar-ray transmittance.

The semiconductor layer 400 may be formed of a silicon-based semiconductor material. Also, the semiconductor layer 400 may be formed in a PIN structure where a P-type semiconductor layer, an I-type semiconductor layer, and an N-type semiconductor layer are deposited in sequence. If forming the semiconductor layer 400 with the PIN structure, the P-type semiconductor layer is firstly formed on the first anti-oxidation layer 300, and then the I-type semiconductor layer and the N-type semiconductor layer are formed thereon, preferably.

The transparent conductive layer 600 may be formed of a transparent conductive material, for example, ZnO. Even though an omission of the transparent conductive layer 600 makes no problem regarding an operation of solar cell, the thin film type solar cell according to the present invention is preferably provided with the transparent conductive layer 600.

The rear electrode 700 may be formed of metal, for example, Ag, Al, Ag+Al, Ag+Mg, Ag+Mn, Ag+Sb, Ag+Zn, Ag+Mo, Ag+Ni, Ag+Cu, or Ag+Al+Zn.

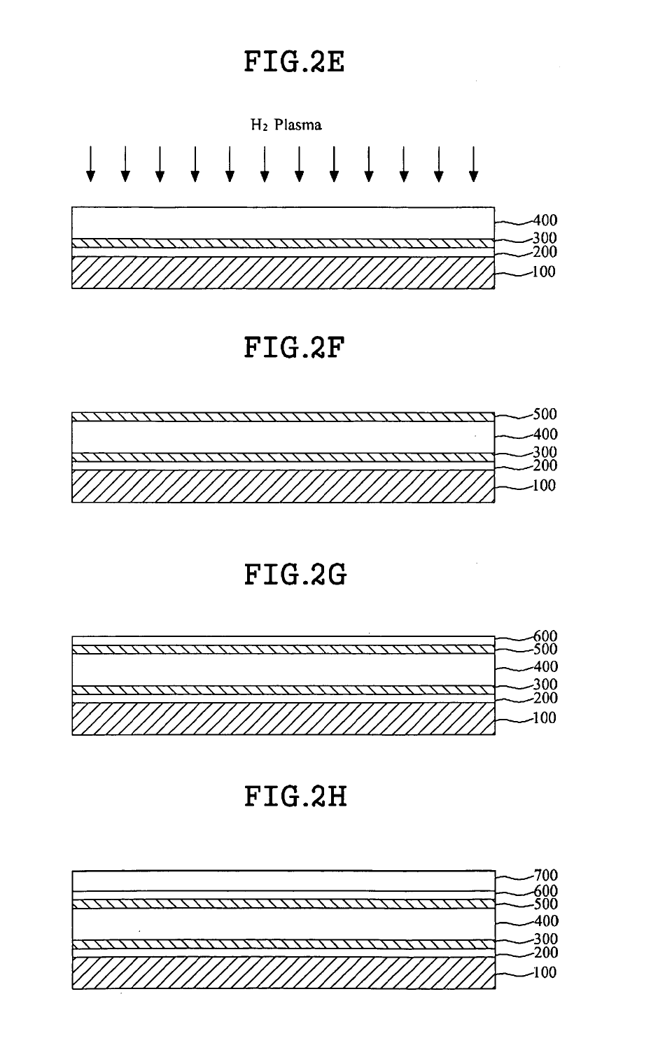

FIG. 4 is a cross section view illustrating a thin film type solar cell according to another embodiment of the present invention. Except that a second anti-oxidation layer 500 is additionally formed between a semiconductor layer 400 and a transparent conductive layer 600, the thin film type solar cell according to another embodiment of the present invention is identical in structure to the thin film type solar cell explained with reference to FIG. 3. Thus, wherever possible, the same reference numbers will be used throughout the drawings to refer to the same or like parts as those of the aforementioned embodiment, and the detailed explanation for the same or like parts will be omitted.

The second anti-oxidation layer 500 prevents an oxide from being formed in the interface between the semiconductor layer 400 and the transparent conductive layer 600. In this case, the second anti-oxidation layer 500 is formed of the same material as that of a first anti-oxidation layer 300. That is, the second anti-oxidation layer 500 may be formed of germanium (Ge), and may be formed at a thickness between 10 Å (1×10⁻¹¹ m) and 30 Å (3×10⁻¹¹ m).

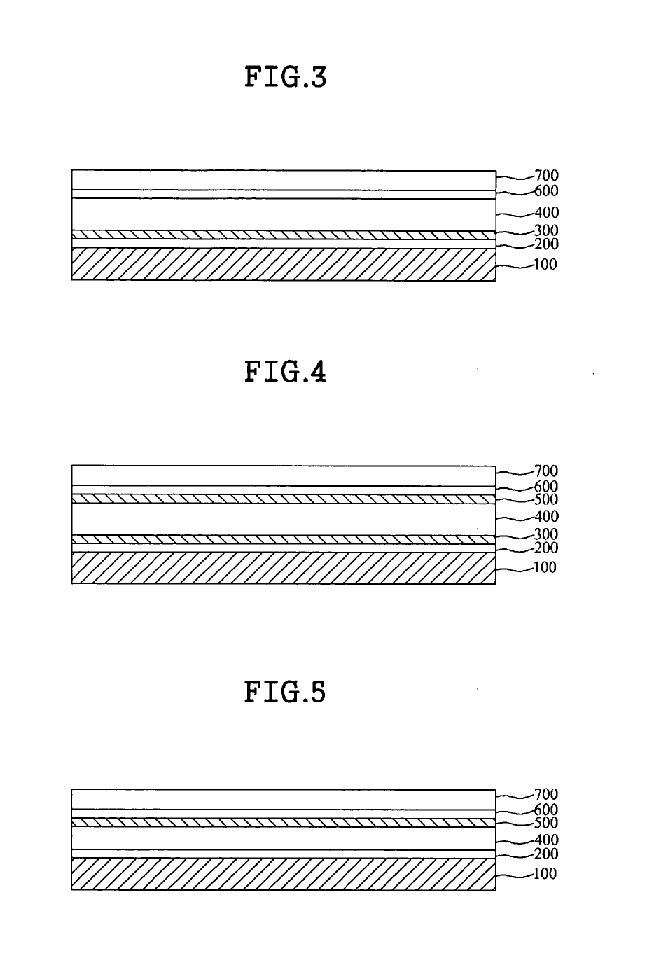

FIG. 5 is a cross section view illustrating a thin film type solar cell according to another embodiment of the present invention. Except that a first anti-oxidation layer 300 is not formed between a front electrode 200 and a semiconductor layer 400, the thin film type solar cell according to another embodiment of the present invention is identical in structure to the thin film type solar cell explained with reference to FIG. 4.

Accordingly, the thin film type solar cell according to the present invention and the method for manufacturing the same has the following advantages.

First, the first anti-oxidation layer 300 is formed on the front electrode 200, and the semiconductor layer 400 is formed on the first anti-oxidation layer 300. Accordingly, it is possible to prevent the reaction between the oxidant contained in the front electrode 200 and the silicon of the semiconductor layer 400, whereby it is possible to prevent the oxide from being formed in the interface between the front electrode 200 and the semiconductor layer 400, thereby resulting in the improved cell efficiency.

Second, the semiconductor layer 400 is formed after removing the oxidant from the front electrode 200 through a hydrogen (H₂) plasma treatment, so that it prevents oxide from being formed in the interface between the front electrode 200 and the semiconductor layer 400, thereby improving the cell efficiency.

Third, the second anti-oxidation layer 500 is formed on the semiconductor layer 400, and the transparent conductive layer 600 is formed on the second anti-oxidation layer 500. Accordingly, it is possible to prevent the reaction between the silicon of the semiconductor layer 400 and the oxidant contained in the transparent conductive layer 600, whereby it is possible to prevent the oxide from being formed in the interface between the semiconductor layer 400 and the transparent conductive layer 600, thereby resulting in the improved cell efficiency.

Fourth, the transparent conductive layer 600 is formed after removing the oxidant from the semiconductor layer 400 through a hydrogen (H₂) plasma treatment, so that it prevents oxide from being formed in the interface between the semiconductor layer 400 and the transparent conductive layer 600, thereby improving the cell efficiency.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A thin film type solar cell comprising:
a front electrode on a substrate;
a first anti-oxidation layer on the front electrode;
a semiconductor layer on the first anti-oxidation layer, such that the first anti-oxidation layer is under the semiconductor layer;
a second anti-oxidation layer on the semiconductor layer, wherein the second anti-oxidation layer comprises a material that does not contain oxygen therein;
a transparent conductive layer on the second anti-oxidation layer; and
a rear electrode on the transparent conductive layer.

2. The thin film type solar cell of claim 1, wherein the second anti-oxidation layer is between the semiconductor layer and the transparent conductive layer.

3. The thin film type solar cell of claim 1, wherein the first anti-oxidation layer comprises a germanium (Ge) layer.

4. The thin film type solar cell of claim 1, wherein the first anti-oxidation layer has a thickness between 10 Å and 30 Å.

5. The thin film type solar cell of claim 1, wherein the second anti-oxidation layer comprises a germanium (Ge) layer.

6. The thin film type solar cell of claim 1, wherein the second anti-oxidation layer has a thickness between 10 Å and 30 Å.

7. The thin film type solar cell of claim 1, wherein the first anti-oxidation layer comprises a material that does not contain oxygen therein.

8. The thin film type solar cell of claim 1, wherein the front electrode comprises a de-oxidized front electrode.

9. The thin film type solar cell of claim 1, wherein the semiconductor layer comprises a de-oxidized semiconductor layer.

10. The thin film type solar cell of claim 1, wherein the front electrode comprises ZnO, ZnO:B, ZnO:Al, ZnO:H, SnO₂, SnO₂:F and/or indium tin oxide (ITO).

11. The thin film type solar cell of claim 1, wherein the second anti-oxidation layer consists essentially of one or more oxygen-free materials.

12. The thin film type solar cell of claim 1, wherein the transparent conductive layer comprises ZnO, ZnO:B, ZnO:Al, ZnO:H, SnO₂, SnO₂:F, and/or ITO (Indium Tin Oxide).

13. The thin film type solar cell of claim 1, wherein the first anti-oxidation layer consists essentially of a germanium (Ge) layer.

14. The thin film type solar cell of claim 13, wherein the second anti-oxidation layer consists essentially of a germanium (Ge) layer.

15. The thin film type solar cell of claim 14, wherein the front electrode comprises ZnO, ZnO:B, ZnO:Al, ZnO:H, SnO₂, SnO₂:F and/or indium tin oxide (ITO).

16. The thin film type solar cell of claim 15, wherein the transparent conductive layer comprises ZnO, ZnO:B, ZnO:Al, ZnO:H, SnO₂, SnO₂:F, and/or ITO (Indium Tin Oxide).

17. The thin film type solar cell of claim 1, wherein the first anti-oxidation layer prevents an oxide from being formed in an interface between the front electrode and the semiconductor layer.

18. The thin film type solar cell of claim 17, wherein the second anti-oxidation layer prevents an oxide from being formed in an interface between the semiconductor layer and the transparent conductive layer.

19. The thin film type solar cell of claim 1, wherein the first anti-oxidation layer scavenges oxygen.

20. The thin film type solar cell of claim 1, wherein the semiconductor layer consists of an oxygen-free material.
